(19) United States
(12) Patent Application Publication
(10) Pub. No.: US 2024/0178100 A1
(43) Pub. Date: May 30, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Naoki YOSHIMATSU, Tokyo (JP); Shintaro ARAKI, Tokyo (JP)

(73) Assignee: Mitsubishi Electric Corporation, Tokyo (JP)

(21) Appl. No.: 18/464,511

(22) Filed: Sep. 11, 2023

(30) Foreign Application Priority Data
Nov. 29, 2022 (JP) 2022-189975

(51) Int. Cl. H01L 23/373; H01L 21/56; H01L 23/00; H01L 23/31; H01L 23/492; H01L 23/495

(52) U.S. Cl. CPC H01L 23/3736; H01L 21/565; H01L 23/3107; H01L 23/4924; H01L 23/4952; H01L 23/49562; H01L 23/49579; H01L 24/45; H01L 2224/45124; H01L 2924/13055

(57) ABSTRACT

The semiconductor device includes: a heat spreader; a first solder layer; a second solder layer; a semiconductor element including a first surface bonded to the heat spreader through the first solder layer, a second surface facing the first surface, a first electrode disposed on the first surface, and a second electrode disposed on the second surface; a block bonded to the second electrode through the second solder layer; a sheet including a first portion, and a second portion having insulating properties and being in contact with the heat spreader; a first lead frame welded to the heat spreader; a second lead frame welded to the block; and a sealant having insulating properties and sealing the first and second lead frames, the heat spreader, the first and second solder layers, the semiconductor element, and the block.

### BACKGROUND OF THE INVENTION

### Field of the Invention

The present disclosure relates to a semiconductor device and a method of manufacturing a semiconductor device.

### Description of the Background Art

Semiconductor devices are provided as, for example, packages each including a semiconductor element sealed by an insulator. Examples of the insulator include a hard resin. The semiconductor devices provided as the packages also include a plurality of components with different linear coefficients of expansion, besides the semiconductor elements. Exposure of the semiconductor devices to environments in heating and cooling cycles expand and contract the plurality of components, and sometimes creates shearing stress on a surface at which components are bonded together (hereinafter, simply referred to as “subject components”). The higher moduli of elasticity of components to be bonded are, the higher the stress becomes. The stress deforms the components, for example, induces warpage. The deformation may induce stress in a portion other than portions with the deformation.

Solder is known as a bonding material for bonding metals. Solder also functions as a stress buffer that deforms to absorb the stress from subject components. Welding, which is a process of bonding subject components together by melting, for example, copper, hardly allows a portion at which the subject components are bonded together to absorb the stress.

An electrode formed on a surface of a semiconductor element (hereinafter also referred to as a “surface electrode”) is made of, for example, aluminum. Aluminum has a modulus of elasticity and a 0.2% proof strength closer to those of solder. The surface electrode is, for example, bonded to a lead part through a block made of a metal. When the surface electrode is bonded to the block through solder, the surface electrode is subject to damages with a higher priority than that of solder, depending on the shape or the size of the surface electrode. Here, solder has a poor function as the stress buffer, thus resulting in large stress. The large stress could conceivably split the surface electrode, and moreover, damage the semiconductor element.

In view of these, a package including a plurality of components with different linear coefficients of expansion desirably has at least any one of, for example, solder and a structure buffering stress (hereinafter also referred to as “stress buffer structure”) in bonding portions of a semiconductor element and portions near the portions. WO2020/105476 exemplifies a structure including: an insulating substrate; a conductive substrate mounted on the insulating substrate; a semiconductor element further mounted on the conductive substrate; a first block made of a metal and bonded to the semiconductor element through a bonding material; and a lead part welded to the first block.

For example, when the lead part is bonded to the first block through solder, the solder functions as a stress buffer and suppresses the stress to be applied to surface electrode.

WO2020/105476 describes a wide variety of materials that can be selected for each of the components to be used. It is desirable that a difference in linear coefficient of expansion between the components included in the package is smaller to reduce the stress to be generated. For example, a low thermal expansion material, e.g., ceramic is used as a material of the insulating substrate. For example, a composite substrate of graphite and a copper film is used as the conductive substrate. For example, invar or kovar is used as a material of the first blocks. For example, a clad material, e.g., copper/invar/copper (CIC) is used as a material of the lead part. These materials are special materials that increases the cost necessary for manufacturing semiconductor devices (hereinafter also referred to as “manufacturing cost”).

Examples of general-purpose materials to be used as much as possible for reducing the manufacturing cost include copper as a material of the conductive substrate or the leads, and sintered copper-molybdenum as a material of the first blocks. These materials are higher in linear coefficient of expansion than ceramic used as a material of a supporting substrate. Applications of these materials bring about warpage of components and the stress between the components, and moreover bring about concerns on reduction in the reliability of semiconductor devices. The reliability obtained from the technology disclosed by WO2020/105476 involves high manufacturing cost.

Japanese Patent Application Laid-Open No. 2008-305902, No. 2008-212977, and No. 2021-190505 may be related to the present disclosure.

### SUMMARY

The present disclosure has an object of contributing to provision of a semiconductor device high in reliability and low in manufacturing cost.

A first aspect of the semiconductor device according to the present disclosure includes: a heat spreader made of copper or a copper alloy; a first solder layer; a second solder layer; a semiconductor element including a first surface bonded to the heat spreader through the first solder layer, a second surface facing the first surface, a first electrode disposed on the first surface, and a second electrode disposed on the second surface; a block bonded to the second electrode through the second solder layer, the block being made of copper or a copper alloy; a sheet including a first portion made of copper or a copper alloy, and a second portion having insulating properties and being in contact with the heat spreader; a first lead frame welded to the heat spreader and made of copper or a copper alloy; a second lead frame welded to the block and made of copper or a copper alloy; and a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the heat spreader, sealing the second lead frame with the second lead frame being partly exposed opposite to the block, and sealing the heat spreader, the first solder layer, the second solder layer, the semiconductor element, and the block.

A second aspect of the semiconductor device according to the present disclosure includes: a heat spreader made of copper or a copper alloy; a first solder layer; a second solder layer; a third solder layer having a melting point lower than a first melting point that is a lower one of a melting point of the first solder layer and a melting point of the second solder layer; a fourth solder layer having a melting point lower than the first melting point; a semiconductor element including a first surface bonded to the heat spreader through the first solder layer, a second surface facing the first surface, a first electrode disposed on the first surface, and a second electrode disposed on the second surface; a block bonded to the second electrode through the second solder layer, the block being made of copper or a copper alloy; a sheet including a first portion made of copper or a copper alloy, and a second portion having insulating properties and being in contact with the heat spreader; a first lead frame bonded to the heat spreader through the third solder layer and made of copper or a copper alloy; a second lead frame bonded to the block through the fourth solder layer and made of copper or a copper alloy; and a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the heat spreader, sealing the second lead frame with the second lead frame being partly exposed opposite to the block, and sealing the heat spreader, the first solder layer, the second solder layer, the semiconductor element, and the block.

A third aspect of the semiconductor device according to the present disclosure includes: a first lead frame; a second lead frame; a housing being tubular and having insulating properties and burying a center of the first lead frame and a center of the second lead frame; a sheet including a circuit pattern made of copper or a copper alloy and bonded to the first lead frame, a first portion made of copper or a copper alloy, and a second portion having insulating properties and sandwiched between the circuit pattern and the first portion, the sheet being housed in the housing with at least a part of the first portion being exposed; a first solder layer housed in the housing; a second solder layer housed in the housing; a semiconductor element including a first surface, a second surface facing the first surface, a first electrode disposed on the first surface and bonded to the circuit pattern through the first solder layer, and a second electrode disposed on the second surface, the semiconductor element being housed in the housing; a block bonded to the second electrode through the second solder layer and bonded to the second lead frame, the block being made of copper or a copper alloy and being housed in the housing; and a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the circuit pattern, sealing the second lead frame with the second lead frame being partly exposed opposite to the block, and sealing the circuit pattern, the first solder layer, the second solder layer, the semiconductor element, and the block.

The present disclosure can provide a semiconductor device high in reliability and low in manufacturing cost.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a cross-sectional view exemplifying a structure of a semiconductor device according to Embodiment 1;

FIG. 2 is a plan view exemplifying the structure of the semiconductor device according to Embodiment 1;

FIG. 3 is a flowchart exemplifying steps of manufacturing the semiconductor device according to Embodiment 1;

FIG. 4 is a cross-sectional view exemplifying the structure after the first step;

FIG. 5 is a cross-sectional view exemplifying the structure after the second step;

FIG. 6 is a cross-sectional view exemplifying the structure after the third step;

FIG. 7 is a cross-sectional view exemplifying the structure after the fourth step;

FIG. 8 is a cross-sectional view exemplifying a structure of a semiconductor device according to Embodiment 2;

FIG. 9 is a plan view exemplifying the structure of the semiconductor device according to Embodiment 2;

FIG. 10 is a cross-sectional view exemplifying a structure of a semiconductor device according to Embodiment 3;

FIG. 11 is a cross-sectional view exemplifying the progress of the third step in steps of manufacturing the semiconductor device according to Embodiment 3;

FIG. 12 is a cross-sectional view exemplifying the progress of the third step in the steps of manufacturing the semiconductor device according to Embodiment 3;

FIG. 13 is a cross-sectional view exemplifying the progress of the third step in the steps of manufacturing the semiconductor device according to Embodiment 3;

FIG. 14 is a cross-sectional view exemplifying the progress of the third step in the steps of manufacturing the semiconductor device according to Embodiment 3;

FIG. 15 is a cross-sectional view exemplifying a structure of a semiconductor device according to Embodiment 4;

FIG. 16 is an enlarged cross-sectional view illustrating a first surface, a second surface, a heat spreader, and a block in the semiconductor device according to Embodiment 4;

FIG. 17 is an enlarged cross-sectional view illustrating the first surface, the second surface, the heat spreader, and the block in the semiconductor device according to Embodiment 4;

FIG. 18 is a partial enlarged plan view illustrating the block, and the semiconductor element and the heat spreader in the vicinity of the block;

FIG. 19 is a partial enlarged cross-sectional view illustrating a protrusion, and the semiconductor element and the heat spreader in the vicinity of the protrusion;

FIG. 20 is a cross-sectional view exemplifying a structure of another semiconductor device according to Embodiment 4;

FIG. 21 is an enlarged cross-sectional view illustrating the first surface, the second surface, the heat spreader, and the block in the structure of the other semiconductor device according to Embodiment 4;

FIG. 22 is an enlarged cross-sectional view illustrating the first surface, the second surface, the heat spreader, and the block in the structure of the other semiconductor device according to Embodiment 4;

FIG. 23 is a partial plan view illustrating the block, and the semiconductor element and the heat spreader in the vicinity of the block;

FIG. 24 is a cross-sectional view exemplifying a structure of a semiconductor device according to Embodiment 5;

FIG. 25 is a cross-sectional view exemplifying a structure of a semiconductor device according to Embodiment 6;

FIG. 26 is a cross-sectional view illustrating a part of steps of manufacturing the semiconductor device according to Embodiment 6;

FIG. 27 is a cross-sectional view illustrating a part of steps of manufacturing the semiconductor device according to Embodiment 6;

FIG. 28 is a flowchart exemplifying the second step in Embodiment 6;

FIG. 29 is a cross-sectional view exemplifying a structure of a semiconductor device according to Embodiment 7;

FIG. 30 is a cross-sectional view illustrating a step of manufacturing the semiconductor device according to Embodiment 7;

FIG. 31 is a cross-sectional view illustrating a step of manufacturing the semiconductor device according to Embodiment 7;

FIG. 32 is a cross-sectional view illustrating a step of manufacturing the semiconductor device according to Embodiment 7; and

FIG. 33 is a flowchart exemplifying steps of manufacturing the semiconductor device according to Embodiment 7.

### DESCRIPTION OF THE PREFERRED EMBODIMENTS

### Embodiment 1

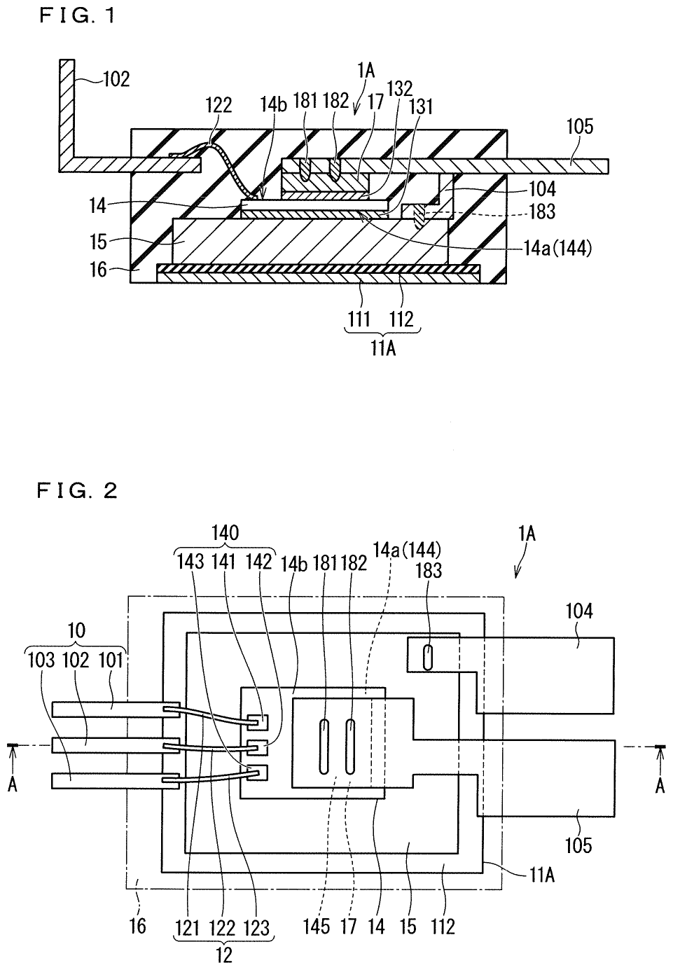

FIG. 1 is a cross-sectional view exemplifying a structure of a semiconductor device 1A according to Embodiment 1 of the present disclosure. The semiconductor device 1A includes a semiconductor element 14, a heat spreader 15, and a block 17 made of a metal, all of which are sealed by a sealant 16.

FIG. 2 is a plan view exemplifying the structure of the semiconductor device 1A. An alternate long and short dashed line of FIG. 2 indicates only a position of the sealant 16 in the plan view to provide better viewability of the structure of the semiconductor device 1A. FIG. 1 is a cross-sectional arrow view taken along the line AA in FIG. 2.

The semiconductor element 14 has a first surface 14a and a second surface 14b that face each other. The semiconductor element 14 has the first surface 14a farther from the block 17, and the second surface 14b closer to the block 17.

The semiconductor element 14 includes a first electrode 144 disposed on the first surface 14a. For example, the first surface 14a is metalized and functions as the first electrode 144. In the drawings, the first surface 14a appears as the first electrode 144, and thus has a reference numeral “14a (144)”. The first surface 14a is bonded to the heat spreader 15 through a first solder layer 131. The heat spreader 15 is made of copper or a copper alloy (a composite of copper and at least one other metal; the same holds true for the following description).

For example, a rolled material made of copper or a copper alloy and 2 to 4 mm thick is adopted as the heat spreader 15. For example, a basis material of the rolled material is used as it is as a portion of the heat spreader 15 to which the first surface 14a is bonded.

The semiconductor element 14 includes a second electrode 145 (illustration omitted in FIG. 1) disposed on the second surface 14b. For example, the second surface 14b is partly metalized, and formed as the second electrode 145. The block 17 is disposed without extending beyond the second electrode 145 in a plan view. FIG. 2 exemplifies that an outline of the block 17 matches that of the second electrode 145 in the plan view. The block 17 is made of copper or a copper alloy. The second surface 14b is bonded to the block 17 through a second solder layer 132. The illustration of the first solder layer 131 and the second solder layer 132 is omitted in FIG. 2.

The semiconductor device 1A further includes a sheet 11A. The sheet 11A includes a first portion 111 and a second portion 112. The first portion 111 is made of copper or a copper alloy. The second portion 112 has insulating properties, and is made of, for example, a resin. The heat spreader 15 is in contact with, for example, adheres to the second portion 112 opposite to the semiconductor element 14.

The semiconductor device 1A further includes a first lead frame 104 and a second lead frame 105. The first lead frame 104 is partially welded and bonded to the heat spreader 15 by laser irradiation from the opposite side of the sheet 11A. A portion (hereinafter also referred to as a “welded portion”) 183 in which the first lead frame 104 is welded to the heat spreader 15 is at a position advanced in a direction of arrows with respect to the line AA. Thus, FIG. 1 illustrates an outline of the welded portion 183 using broken lines that are hidden lines.

The second lead frame 105 is partially welded and bonded to the block 17 on a side opposite to the semiconductor element 14. For example, the second lead frame 105 is partially welded and bonded to the block 17 at welded portions 181 and 182 by laser irradiation from the opposite side of the semiconductor element 14. The welding by laser irradiation contributes to improvement on the productivity.

Each of the block 17, the heat spreader 15, the first lead frame 104, and the second lead frame 105 is made of copper or a copper alloy. Since the laser light melts copper or a copper alloy material in the welding, a range to be heated is limited, and other portions are hardly thermally damaged.

When an insulated gate bipolar transistor (hereinafter abbreviated as an “IGBT”) is used as the semiconductor element 14, the first electrode 144 functions as a collector electrode, and the second electrode 145 functions as an emitter electrode.

The first lead frame 104 becomes conductive with the first electrode 144 through the heat spreader 15, and functions as a collector terminal of the IGBT functioning as the semiconductor element 14. The second lead frame 105 becomes conductive with the second electrode 145 through the block 17, and functions as an emitter terminal of the IGBT. When the IGBT operates, a collector current flows through the first lead frame 104, and an emitter current flows through the second lead frame 105.

The semiconductor element 14 further includes an electrode group 140 (illustration omitted in FIG. 1) disposed on the second surface 14b. The electrode group 140 includes third electrodes 141, 142, and 143. For example, the third electrode 141 is a gate electrode of the IGBT functioning as the semiconductor element 14, and receives a gate signal for controlling ON and OFF of the IGBT. For example, the third electrode 142 receives a signal for detecting an emitter voltage of the IGBT. For example, the third electrode 143 receives a signal for protecting the IGBT, for example, a signal with information on a temperature or information on a current value.

The semiconductor device 1A further includes a lead frame group 10 and a wire group 12. The lead frame group 10 includes third lead frames 101, 102, and 103. The third lead frames 101, 102, and 103 contain copper or a copper alloy. The wire group 12 includes wires 121, 122, and 123. The wires 121, 122, and 123 contain, for example, aluminum or an aluminum alloy. The third lead frame 101 is connected to the third electrode 141 through the wire 121. The third lead frame 102 is connected to the third electrode 142 through the wire 122. The third lead frame 103 is connected to the third electrode 143 through the wire 123.

The sealant 16 seals the first lead frame 104, the second lead frame 105, the heat spreader 15, the lead frame group 10, the first solder layer 131, the second solder layer 132, the semiconductor element 14, and the block 17. The sealant 16 exposes at least a part of the first portion 111 (a surface of the first portion 111 opposite to the second portion 112), partly exposes the first lead frame 104 opposite to the heat spreader 15, partly exposes the second lead frame 105 opposite to the block 17, and partly exposes the lead frame group 10 opposite to the electrode group 140.

For example, resin transfer molding is adopted as the sealing using the sealant 16. Before the transfer molding, the first lead frame 104, the second lead frame 105, and the lead frame group 10 form a linked portion having a thickness of 0.5 mm to 1.0 mm and made of copper or a copper alloy. After the transfer molding, the first lead frame 104, the second lead frame 105, and the lead frame group 10 are separated, for example, by cutting. For example, the lead frame group 10 is bent into the exemplified shape as necessary.

For example, copper foil approximately 0.1 mm thick is used as the first portion 111 of the sheet 11A. For example, an insulating resin approximately 0.1 to 0.3 mm thick is used as the second portion 112. The second portion 112 is evenly applied to the first portion 111 and is heat pressed up to what is called a B-stage (a semi-cured state) to prepare the sheet 11A. The second portion 112 in this state receives the pressure from the sealant 16 by the transfer molding, and is exposed to a temperature of a mold to be adopted in the transfer molding to transition to what is called a C-stage (a completely cured state). In this manner, the second portion 112 adheres to the sealant 16 and the heat spreader 15.

For example, the basis material of the rolled material is used as it is as a portion of the heat spreader 15 in contact with the second portion 112.

A portion of the heat spreader 15 in contact with the sealant 16 is, for example, dimpled by pressing it. Dimples obtained from this pressing easily fit the sealant 16, and suppress peels of the sealant 16. Suppressing the peels prevents moisture ingress from outside of the sealant 16 into the constituent elements sealed by the sealant 16. Suppressing the peels also prevents the constituent elements sealed by the sealant 16 from moving. This contributes to maintaining the reliability of bonding the first solder layer 131 and the second solder layer 132 and the reliability of connection between the lead frame group 10 and the electrode group 140 through the wire group 12 for a long period of time.

The sealant 16 is made of an insulating material with a linear coefficient of expansion more than or equal to 11 ppm/K and less than or equal to 21 ppm/K. The sealant 16 is, for example, a thermosetting hard resin obtained by mixing fillers into a resin made of an epoxy system or a polyimide system as a main component. The linear coefficient of expansion of the sealant 16 may widely range approximately from 7 to 40 ppm/K. Controlling, for example, a compounding ratio of the fillers to the resin, or the size or the shape of the fillers leads to a linear coefficient of expansion ranging from 11 to 21 ppm/K.

Linear coefficients of expansions of general copper or copper alloys fall within the range of 11 to 21 ppm/K. Thus, a difference in linear coefficient of expansion between the sealant 16 and each of the block 17, the heat spreader 15, the first lead frame 104, and the second lead frame 105 is small. The small differences reduce the stress in the cooling/heating cycles, and moreover contribute to enhancement of the reliability of semiconductor devices. Application of the block 17, the heat spreader 15, the first lead frame 104, and the second lead frame 105 each made of copper or a copper alloy contributes to reduced material cost and processing cost and even to reduced manufacturing cost.

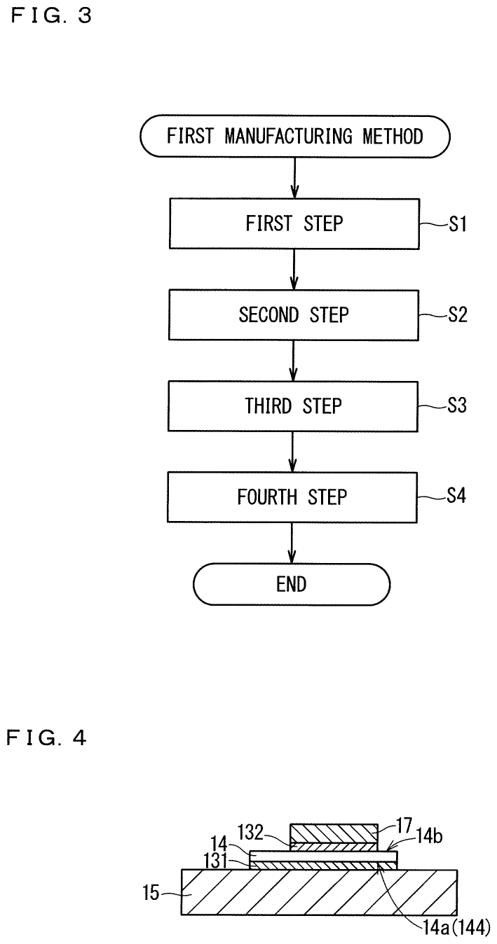

FIG. 3 is a flowchart exemplifying, as a first manufacturing method, steps of manufacturing the semiconductor device 1A (also referred to as “manufacturing steps” in this disclosure with steps of manufacturing semiconductor devices 1B to 1G to be described later). The first manufacturing method includes Steps S1, S2, S3, and S4. In Step S1, a first step is executed. In Step S2, a second step is executed. In Step S3, a third step is executed. In Step S4, a fourth step is executed.

In the first step, the heat spreader 15 and the block 17 are bonded to the semiconductor element 14. FIG. 4 is a cross-sectional view exemplifying the structure after the first step. The location of the cross-section of FIG. 1 is used in FIG. 4. In the first step, the first surface 14a of the semiconductor element 14 is bonded to the heat spreader 15 through the first solder layer 131. For example, known soldered joint is adopted to the bonding. The block 17 is bonded to the second surface 14b of the semiconductor element 14, specifically, the second electrode 145 (illustration omitted in FIGS. 4 to 7; see FIG. 2) through the second solder layer 132. For example, known soldered joint is adopted to the bonding.

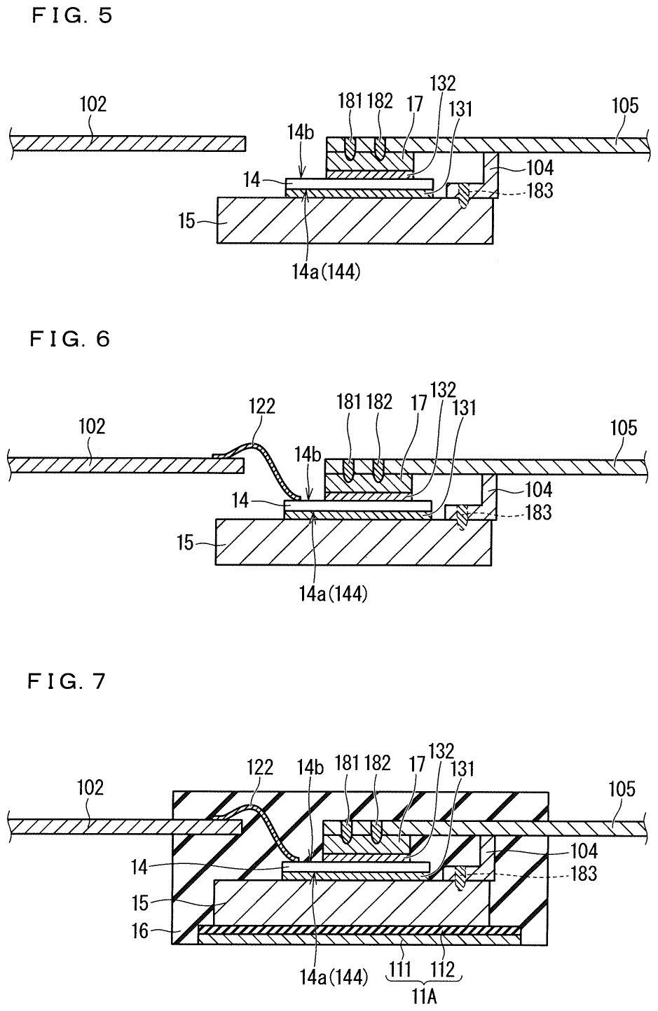

In the second step, the first lead frame 104 is welded to the heat spreader 15, and the second lead frame 105 is welded to the block 17. FIG. 5 is a cross-sectional view exemplifying the structure after the second step. The location of the cross-section of FIG. 1 is used in FIG. 5. In executing the second step, the first lead frame 104, the second lead frame 105, and the lead frame group 10 are prepared as one linked component. FIGS. 5 to 7 omit the structure illustrating such a link.

The first lead frame 104 is welded to the heat spreader 15 by laser irradiation from the first lead frame 104 side to form the welded portion 183. The second lead frame 105 is welded to the block 17 by laser irradiation from the second lead frame 105 side to form the welded portions 181 and 182.

In the third step, the lead frame group 10 and the electrode group 140 are connected through the wire group 12. FIG. 6 is a cross-sectional view exemplifying the structure after the third step. Specifically, the third lead frame 101 is connected to the third electrode 141 through the wire 121, the third lead frame 102 is connected to the third electrode 142 through the wire 122, and the third lead frame 103 is connected to the third electrode 143 through the wire 123 (illustration omitted in FIGS. 4 to 7; see FIG. 2). For example, a known wire bonding technology is adopted to the connections. The location of the cross-section of FIG. 1 is used in FIG. 6. Thus, FIG. 6 does not illustrate the third lead frames 101 and 103 and the wires 121 and 123.

In the fourth step, the sheet 11A is disposed on the heat spreader 15 opposite to the semiconductor element 14. The sealant 16 seals the first lead frame 104, the second lead frame 105, the heat spreader 15, the lead frame group 10, the first solder layer 131, the second solder layer 132, the semiconductor element 14, and the block 17 while exposing the various portions as described above. Thus, the fourth step is a sealing step for forming the sealant 16.

For example, the resin transfer molding is adopted as the sealing using a mold that is not illustrated. As described above, a state of the second portion 112 transitions from the B-stage (semi-cured state) to the C-stage (completely cured state) in the sealing. FIG. 7 is a cross-sectional view exemplifying the structure after the fourth step. The location of the cross-section of FIG. 1 is used in FIG. 7.

In the fourth step, the first lead frame 104, the second lead frame 105, and the lead frame group 10 are separated and bent into desired shapes to obtain the structure illustrated in FIG. 1.

### Embodiment 2

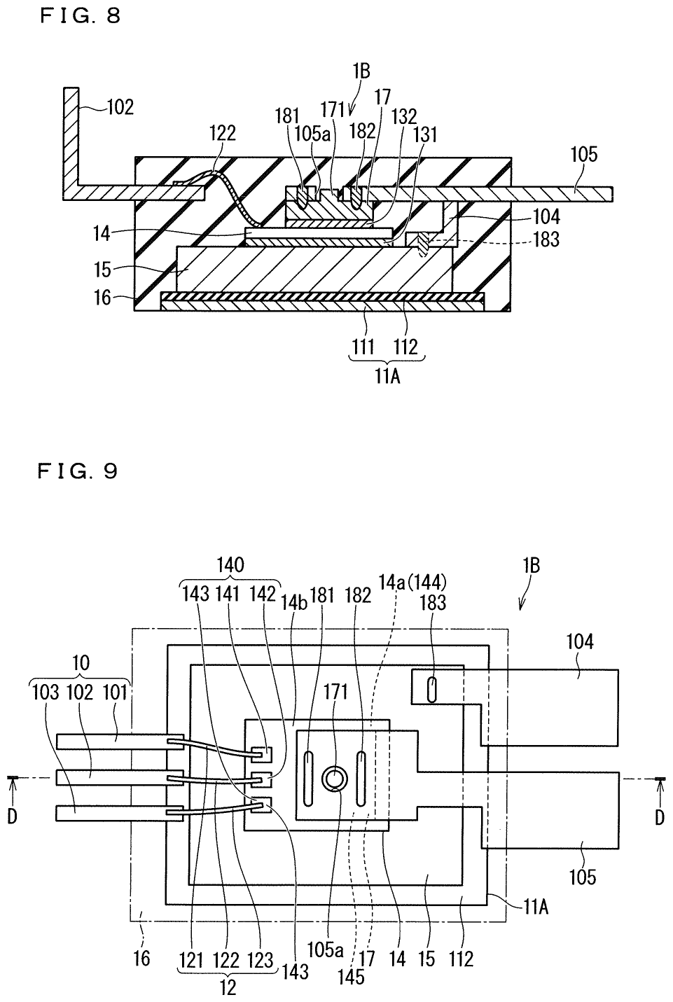

FIG. 8 is a cross-sectional view exemplifying a structure of a semiconductor device 1B according to Embodiment 2 of the present disclosure. A hole 105a is opened in the second lead frame 105 included in the semiconductor device 1B. The hole 105a is adjacent to portions bonded to the block 17, for example, the welded portions 181 and 182. The block 17 included in the semiconductor device 1B according to Embodiment 2 includes a protrusion 171. The protrusion 171 protrudes opposite to the semiconductor element 14, and is inside the hole 105a. The other constituent elements and the relationship between the constituent elements are identical to those of the semiconductor device 1A.

FIG. 9 is a plan view exemplifying the structure of the semiconductor device 1B. An alternate long and short dashed line of FIG. 9 indicates only a position of the sealant 16 in the plan view to provide better viewability of the structure of the semiconductor device 1B. FIG. 8 is a cross-sectional arrow view taken along the line DD in FIG. 9. FIG. 9 exemplifies a case where the hole 105a and the protrusion 171 are sandwiched between the welded portions 181 and 182. The illustration of the first solder layer 131 and the second solder layer 132 is omitted in FIG. 9.

In Embodiment 2, the semiconductor device 1B is also fabricated by, for example, the first to fourth steps described in Embodiment 1. In the second step, engaging the protrusion 171 into the hole 105a easily determines the position of the second lead frame 105 with respect to the block 17. In executing the second step, the first lead frame 104, the second lead frame 105, and the lead frame group 10 are prepared as one linked component. Easily determining the position of the second lead frame 105 with respect to the block 17 also easily determines the position of the first lead frame 104 with respect to the heat spreader 15 and also the position of the lead frame group 10 with respect to the electrode group 140.

The hole 105a and the protrusion 171 contribute not only to positioning of the second lead frame 105 with respect to the block 17 when they are welded, but also to positioning of the first lead frame 104 with respect to the heat spreader 15 when they are welded and moreover to facilitating execution of the second step.

The hole 105a and the protrusion 171 also contribute not only to positioning of the lead frame group 10 with respect to the electrode group 140 when they are connected through the wire group 12, but also to facilitating execution of the third step.

### Embodiment 3

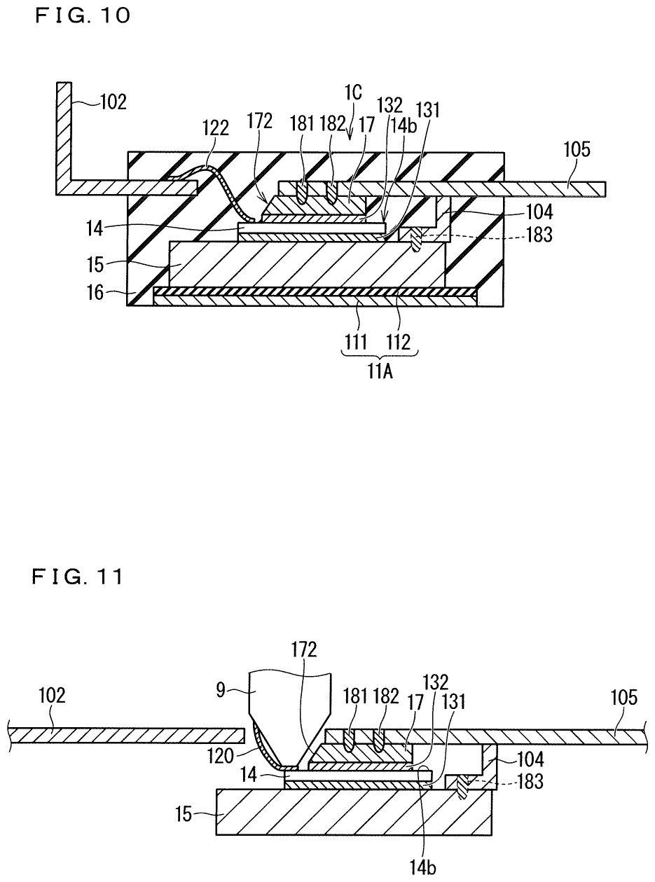

FIG. 10 is a cross-sectional view exemplifying a structure of a semiconductor device 1C according to Embodiment 3 of the present disclosure. The location of the cross-section of FIG. 1 is used in FIG. 10.

The block 17 included in the semiconductor device 1C includes a surface 172. The surface 172 is closer to the third lead frames 101, 102, and 103. A distance between the surface 172 and each of the third lead frames 101, 102, and 103 increases with distance away from the second surface 14b. The other constituent elements and the relationship between the constituent elements are identical to those of the semiconductor device 1A.

In Embodiment 3, the semiconductor device 1C is also fabricated by, for example, the first to fourth steps described in Embodiment 1. FIGS. 11 to 14 are cross-sectional views exemplifying the progress of the third step in steps of manufacturing the semiconductor device 1C. The location of the cross-section of FIG. 10 is used in FIGS. 11 to 14.

An aluminum wire 120 is supplied from the side of a bonding tool 9. FIG. 11 exemplifies a state where an apex of the bonding tool 9 closer to the heat spreader 15 (hereinafter simply referred to as an “apex”) connects the aluminum wire 120 to the third electrode 142 (not illustrated; see FIG. 2).

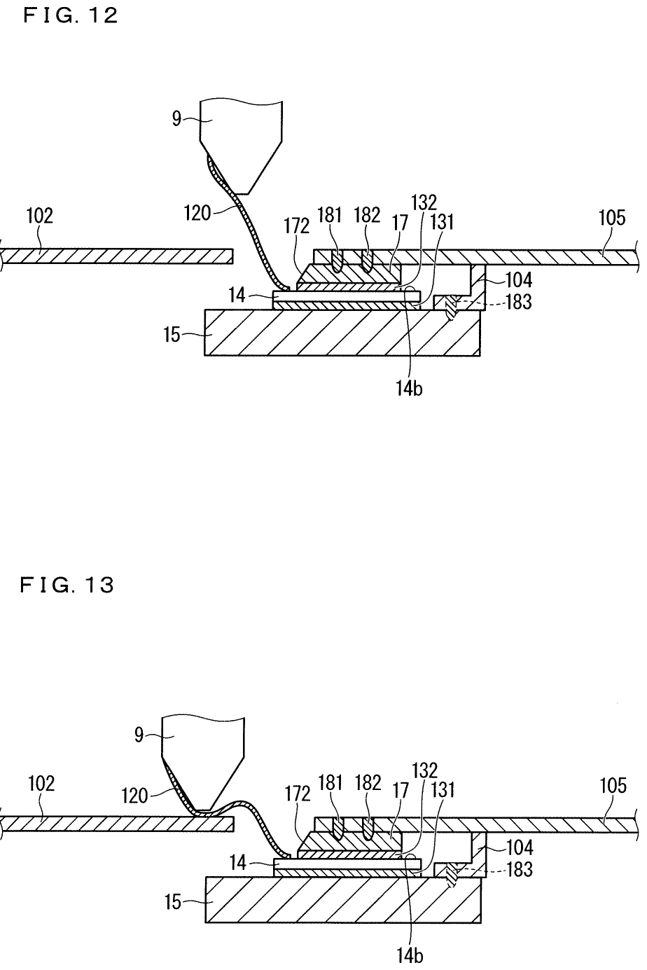

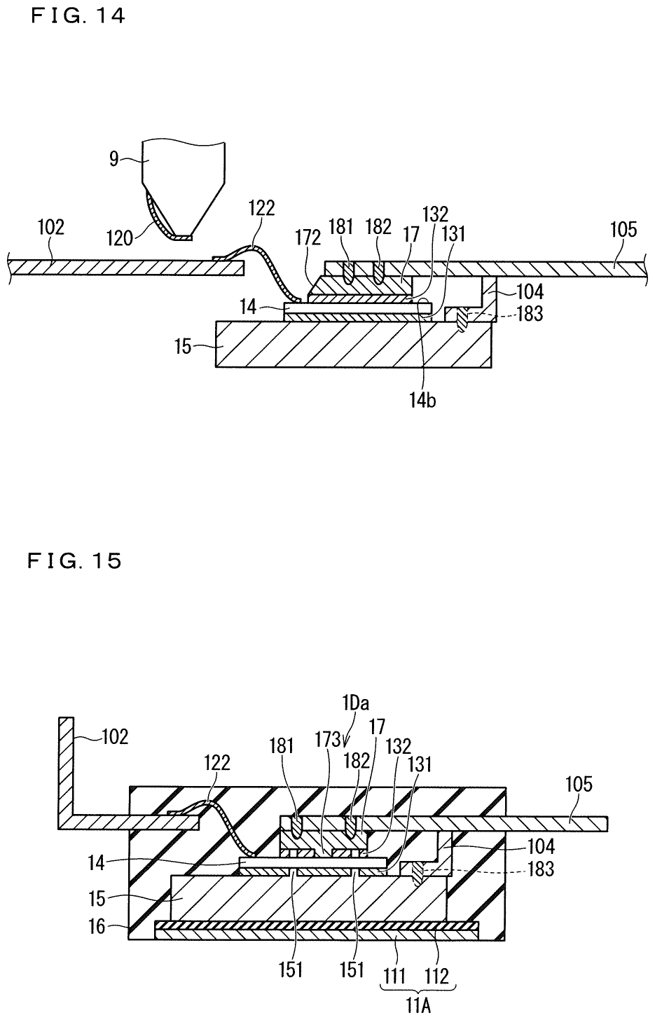

FIG. 12 exemplifies a halfway state of the bonding tool 9, after the connection, which is moving toward the third lead frame 102 while supplying the aluminum wire 120. FIG. 13 exemplifies a state where the apex of the bonding tool 9 connects the aluminum wire 120 to the third lead frame 102. FIG. 14 exemplifies a state after the apex of the bonding tool 9 separates the aluminum wire 120 from the third lead frame 102 to form the wire 122.

Typically, the bonding tool 9 has a widespread shape in an extension direction of the second surface 14b when seen from the apex. When the aluminum wire 120 is connected to the third electrode 142, the apex comes in proximity to the semiconductor element 14. The proximity causes interference between the position of the bonding tool 9 and that of the block 17.

The distance between the surface 172 and each of the third lead frames 101, 102, and 103 increases with distance away from the second surface 14b. This facilitates avoiding the interference between the position of the bonding tool 9 and that of the block 17.

The wires 121, 122, and 123 are easily formed in the semiconductor device 1C. In the semiconductor device 1C, extension of the second electrode 145 closer to the third electrodes 141, 142, and 143 is easily designed. The wider second electrode 145 contributes to reduced ON resistance of the semiconductor element 14.

### Embodiment 4

FIG. 15 is a cross-sectional view exemplifying a structure of a semiconductor device 1Da according to Embodiment 4 of the present disclosure. The location of the cross-section of FIG. 1 is used in FIG. 15.

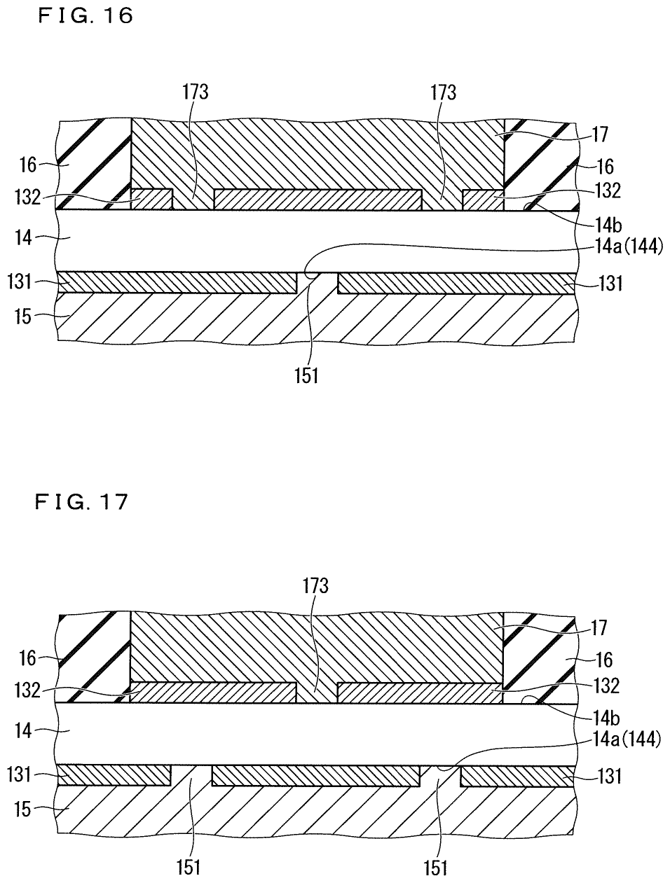

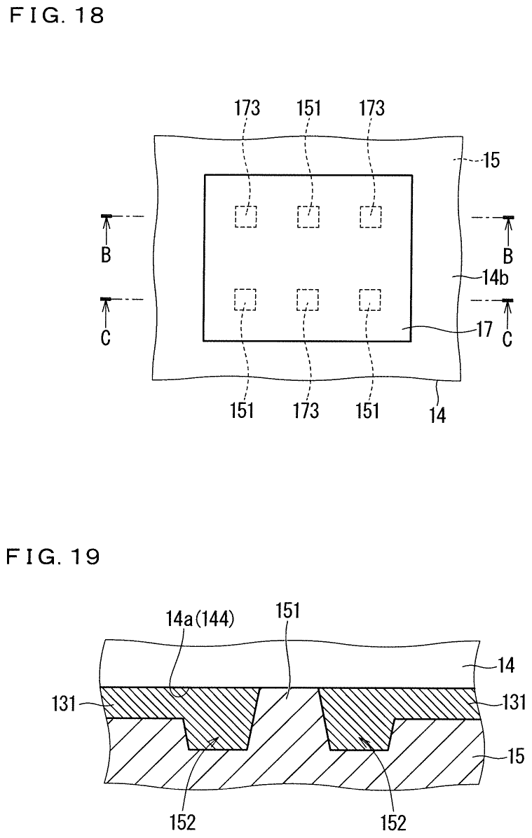

FIGS. 16 and 17 are enlarged cross-sectional views of the heat spreader 15 and the block 17, each illustrating, in the semiconductor device 1Da, the heat spreader 15 in contact with the first surface 14a, the block 17 in contact with the second surface 14b, and the first surface 14a, and the second surface 14b. FIG. 18 is a partial enlarged plan view illustrating the block 17, and the semiconductor element 14 and the heat spreader 15 in the vicinity of the block 17. The illustration of the first solder layer 131 and the second solder layer 132 is omitted in FIG. 18. FIG. 16 is a cross-sectional view taken along the line BB in FIG. 18. FIG. 17 is a cross-sectional view taken along the line CC in FIG. 18.

The block 17 includes protrusions 173 protruding toward the semiconductor element 14. The protrusions 173 are in contact with the second surface 14b. The block 17 includes, for example, three or more of the protrusions 173. The heat spreader 15 includes protrusions 151 protruding toward the semiconductor element 14. The protrusions 151 are in contact with the first surface 14a. The heat spreader 15 includes, for example, three or more of the protrusions 151. The other constituent elements and the relationship between the constituent elements are identical to those of the semiconductor device 1A.

FIGS. 15 to 18 exemplify that the semiconductor device 1Da includes the three protrusions 151 and the three protrusions 173. FIGS. 15 to 18 exemplify that the two protrusions 173 and the one protrusion 151 form one row, the other one protrusion 173 and the other two protrusions 151 form another row, and the two rows are approximately parallel to each other in a plan view.

In Embodiment 4, the semiconductor device 1Da is also fabricated by, for example, the first to fourth steps described in Embodiment 1.

The semiconductor element 14 is thinner in view of reducing the losses, and is, for example, several tens of micrometers thick. When the semiconductor element 14 is curved by the weight of the block 17 in the first step, the second solder layer 132 being melted easily extends beyond the second surface 14b. The protrusions 173 prevent the extension.

When the semiconductor element 14 is curved by the weight of the block 17, the first solder layer 131 being melted easily extends beyond the first surface 14a. The protrusions 151 prevent the extension.

FIG. 19 is a partial enlarged cross-sectional view illustrating the protrusion 151, and the semiconductor element 14 and the heat spreader 15 in the vicinity of the protrusion 151. The protrusion 151 is formed by, for example, press working using a die with annular protrusions when the heat spreader 15 is manufactured. This formation forms an annular groove 152 around the protrusion 151. The protrusion 151 and the groove 152 contribute to enhancement of the reliability of bonding the heat spreader 15 to the semiconductor element 14 through the first solder layer 131.

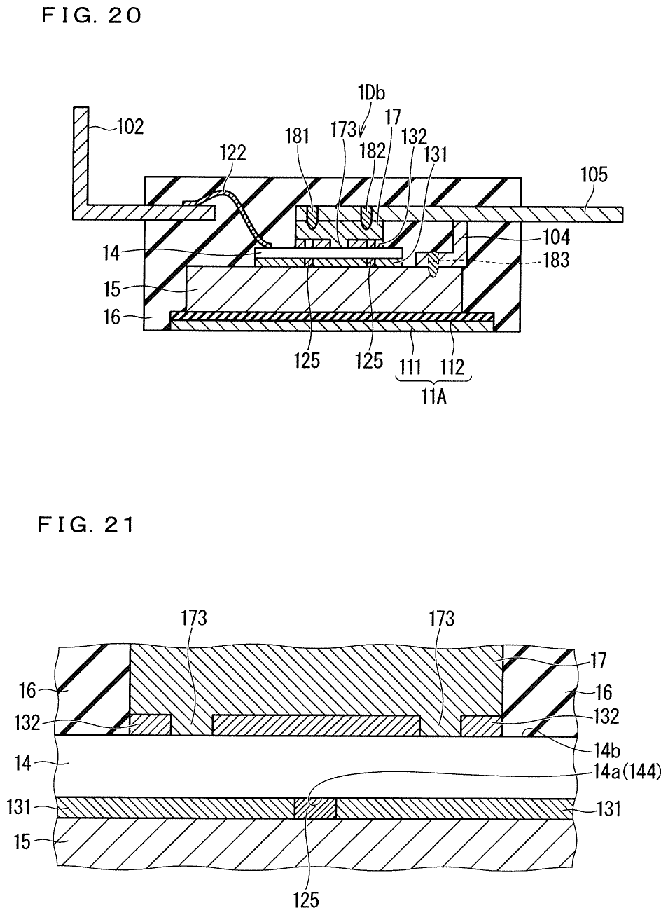

FIG. 20 is a cross-sectional view exemplifying a structure of another semiconductor device 1Db according to Embodiment 4. The location of the cross-section of FIG. 1 is used in FIG. 20.

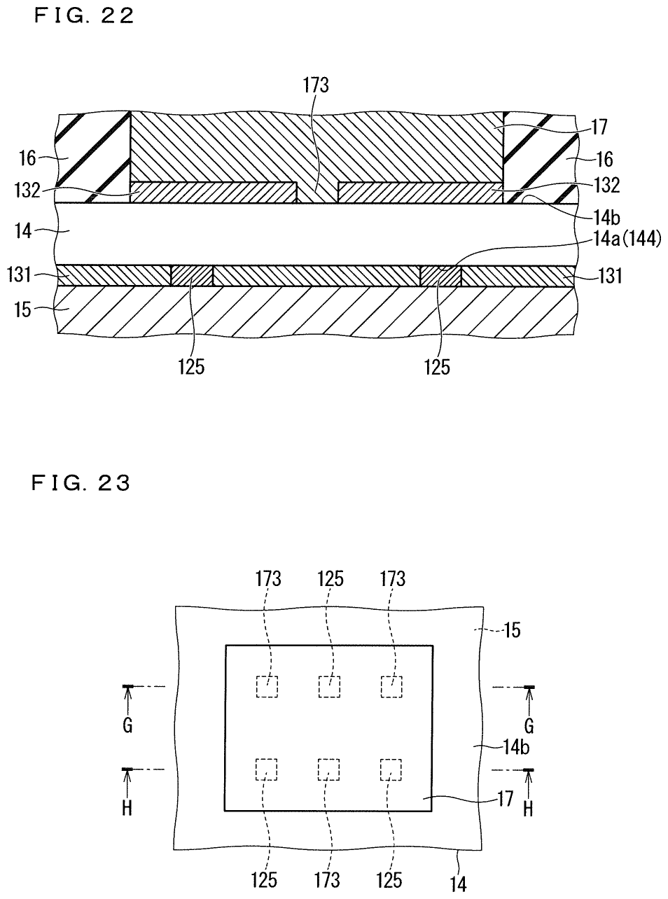

FIGS. 21 and 22 are enlarged cross-sectional views of the heat spreader 15 and the block 17, each illustrating, in the semiconductor device 1Db, the heat spreader 15 in contact with the first surface 14a, the block 17 in contact with the second surface 14b, and the first surface 14a, and the second surface 14b. FIG. 23 is a partial plan view illustrating the block 17, and the semiconductor element 14 and the heat spreader 15 in the vicinity of the block 17. The illustration of the first solder layer 131 and the second solder layer 132 is omitted in FIG. 23. FIG. 21 is a cross-sectional view taken along the line GG in FIG. 23. FIG. 22 is a cross-sectional view taken along the line HH in FIG. 23.

The block 17 includes the aforementioned protrusions 173. The semiconductor device 1Db includes, between the heat spreader 15 and the first surface 14a, bumps 125 made of a metal. The bumps 125 are in contact with the first surface 14a and the heat spreader 15. The semiconductor device 1Db includes, for example, three or more of the bumps 125. The bumps 125 are formed by, for example, a known wire bonding technology.

FIGS. 20 to 23 exemplify that the semiconductor device 1Db includes the three protrusions 173 and the three bumps 125. FIGS. 20 to 23 exemplify that the two protrusions 173 and the one bump 125 form one row, the other one protrusion 173 and the other two bumps 125 form another row, and the two rows are approximately parallel to each other in a plan view.

The bumps 125 prevent the first solder layer 131 being melted from extending beyond the first surface 14a, similarly to the protrusions 151.

The protrusions 151 and 173 and the bumps 125 are not exclusively adopted. For example, both of the protrusions 151 and the bumps 125 are adopted. In this case, the total number of the protrusions 151 and the bumps 125 is, for example, three or more.

The three or more protrusions 173 contribute to stably disposing the block 17 on the semiconductor element 14. The three or more of the protrusions 151 and the bumps 125 in total (including a case where the semiconductor device 1Db does not include the protrusions 151 or the bumps 125) contribute to stably disposing the semiconductor element 14 on the heat spreader 15.

### Embodiment 5

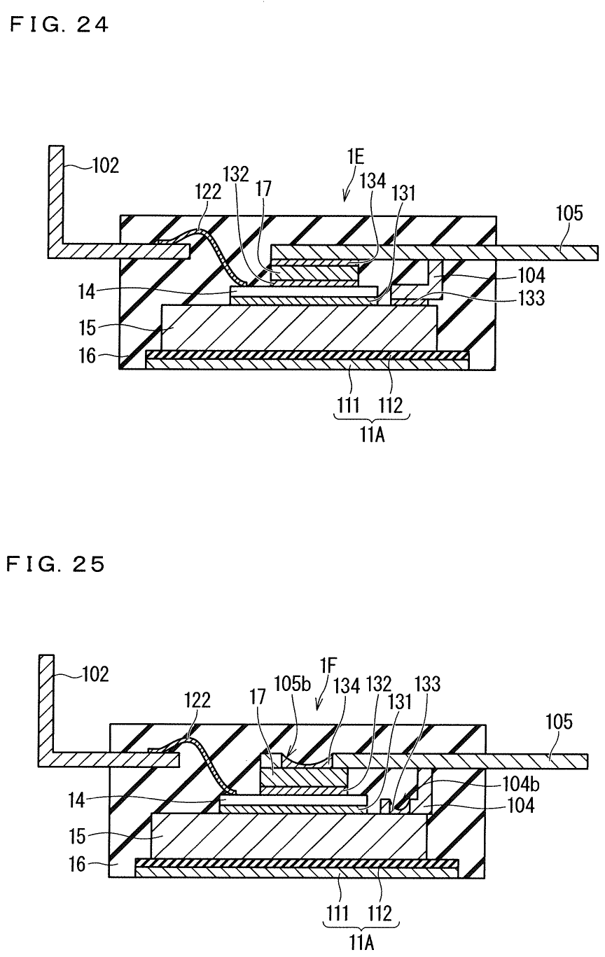

FIG. 24 is a cross-sectional view exemplifying a structure of a semiconductor device 1E according to Embodiment 5 of the present disclosure. The location of the cross-section of FIG. 1 is used in FIG. 24.

The first lead frame 104 is bonded to the heat spreader 15 through a third solder layer 133 in Embodiment 5, unlike Embodiments 1 to 4. The second lead frame 105 is bonded to the block 17 through a fourth solder layer 134 in Embodiment 5, unlike Embodiments 1 to 4. The other constituent elements and the relationship between the constituent elements are identical to those of the semiconductor device 1A.

In Embodiment 5, the semiconductor device 1E is also fabricated by, for example, the first to fourth steps described in Embodiment 1. In the second step according to Embodiment 5, a solder alloy is disposed each between the heat spreader 15 and the first lead frame 104 and between the block 17 and the second lead frame 105. Melting these solder alloys produces the third solder layer 133 and the fourth solder layer 134.

For example, the solder alloy between the heat spreader 15 and the first lead frame 104 is locally heated by laser irradiation through the first lead frame 104, and is melted into the third solder layer 133. The solder alloy between the block 17 and the second lead frame 105 is locally heated by laser irradiation through the second lead frame 105, and is melted into the fourth solder layer 134.

It is preferred to melt the solder alloys to form the third solder layer 133 and the fourth solder layer 134, without melting the first solder layer 131 and the second solder layer 132. This is because melting the first solder layer 131 and the second solder layer 132 may lead to elution of metals (for example, nickel) from the first electrode 144 and the second electrode 145, respectively, and avoidance of such elution is desirable.

Taking into account that the heat spreader 15 and the block 17 contain copper or a copper alloy and have high thermal conductivity, it is preferred that each of a melting point of the third solder layer 133 and a melting point of the fourth solder layer 134 is lower than a first melting point that is a lower one of a melting point of the first solder layer 131 and a melting point of the second solder layer 132.

In the laser irradiation, for example, the heat spreader 15, the semiconductor element 14, and the block 17 are heated lower than the first melting point. The heating contributes to easy formation of the third solder layer 133 and the fourth solder layer 134 by laser irradiation while avoiding melting the first solder layer 131 and the second solder layer 132.

The third solder layer 133 functions as a stress buffer, and contributes to enhancement of the reliability of bonding the first lead frame 104 to the heat spreader 15 at low cost and moreover enhancement of the reliability of the semiconductor device 1E at low cost. The fourth solder layer 134 functions as a stress buffer, and contributes to enhancement of the reliability of bonding the second lead frame 105 to the block 17 at low cost and moreover enhancement of the reliability of the semiconductor device 1E at low cost.

### Embodiment 6

FIG. 25 is a cross-sectional view exemplifying a structure of a semiconductor device 1F according to Embodiment 6 of the present disclosure. The location of the cross-section of FIG. 1 is used in FIG. 25.

In Embodiment 6, a hole 104b is opened in the first lead frame 104, and a hole 105b is opened in the second lead frame 105. The third solder layer 133 is inside the hole 104b, and bonds the first lead frame 104 to the heat spreader 15. The fourth solder layer 134 is inside the hole 105b, and bonds the second lead frame 105 to the block 17. The other constituent elements and the relationship between the constituent elements are identical to those of the semiconductor device 1E.

In Embodiment 6, the semiconductor device 1F is also fabricated by, for example, the first to fourth steps described in Embodiment 1.

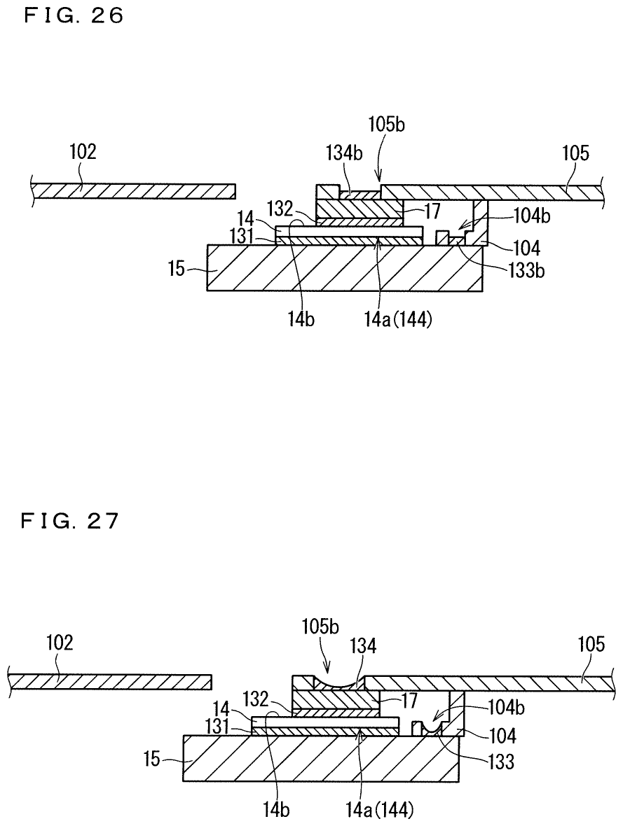

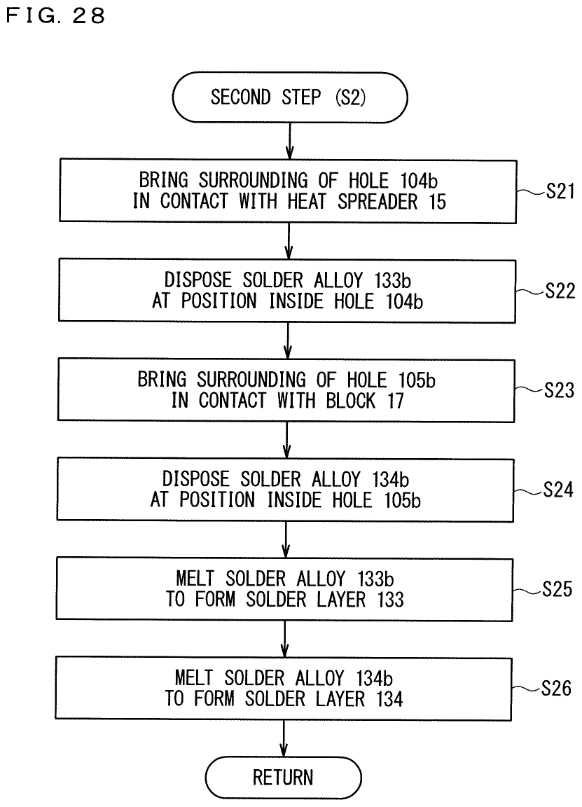

FIGS. 26 and 27 are cross-sectional views illustrating a part of steps of manufacturing the semiconductor device 1F. FIG. 28 is a flowchart exemplifying the second step in Embodiment 6.

The second step in Embodiment 6 includes Steps S21, S22, S23, S24, S25 and S26. A process of Step S21 is to bring the surrounding of the hole 104b in contact with the heat spreader 15. After Step S21, Step S22 is executed. A process of Step S22 is to dispose a first solder alloy 133b at a position inside the hole 104b (see FIG. 26).

A process of Step S23 is to bring the surrounding of the hole 105b in contact with the block 17. After Step S23, Step S24 is executed. A process of Step S24 is to dispose a second solder alloy 134b at a position inside the hole 105b (see FIG. 26). For example, Steps S21 and S23 are simultaneously executed. For example, Steps S22 and S24 are simultaneously executed.

After Steps S21, S22, S23, and S24, Steps S25 and S26 are executed. A process of Step S25 is to melt the first solder alloy 133b to form the third solder layer 133. A process of Step S26 is to melt the second solder alloy 134b to form the fourth solder layer 134 (see FIG. 27). For example, Steps S25 and Step S26 are simultaneously executed.

After Steps S25 and S26, the manufacturing steps return to the third step (Step S3; see FIG. 3).

For example, the first solder alloy 133b is locally heated by laser irradiation into a region inside the hole 104b, and is melted into the third solder layer 133. The second solder alloy 134b is locally heated by laser irradiation into a region inside the hole 105b, and is melted into the fourth solder layer 134. FIGS. 25 and 27 exemplify that the third solder layer 133 and the fourth solder layer 134 are recessed opposite to the heat spreader 15.

As described in Embodiment 5, it is preferred that each of the melting point of the third solder layer 133 and the melting point of the fourth solder layer 134 is lower than the first melting point that is a lower one of the melting point of the first solder layer 131 and the melting point of the second solder layer 132. Here, the first solder alloy 133b in Step S25 and the second solder alloy 134b in Step S26 are melted at a temperature lower than the first melting point.

The semiconductor device 1F has the same advantages as those of the semiconductor device 1E in forming the third solder layer 133 and the fourth solder layer 134. The laser irradiation into the first solder alloy 133b does not involve the first lead frame 104. The laser irradiation into the second solder alloy 134b does not involve the second lead frame 105.

The semiconductor device 1F has an advantage of enabling visual inspection of bonding of the third solder layer 133 and the fourth solder layer 134 prior to the fourth step. This advantage contributes to enhancement of the reliability of bonding the first lead frame 104 to the heat spreader 15, the reliability of bonding the second lead frame 105 to the block 17, and moreover the reliability of the semiconductor device 1F.

### Embodiment 7

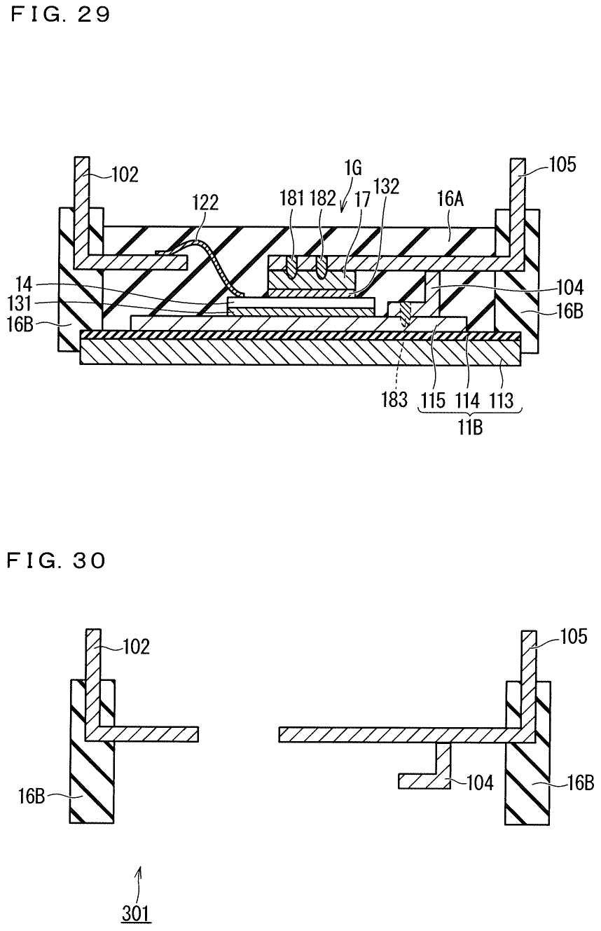

FIG. 29 is a cross-sectional view exemplifying a structure of a semiconductor device 1G according to Embodiment 7 of the present disclosure. The location of the cross-section of FIG. 1 is used in FIG. 29.

The semiconductor device 1G includes the first lead frame 104, the second lead frame 105, and a housing 16B.

The housing 16B is tubular and has insulating properties. The housing 16B buries the center of the first lead frame 104, and the center of the second lead frame 105.

The semiconductor device 1G further includes a sheet 11B, the first solder layer 131, the second solder layer 132, the semiconductor element 14, and the block 17 all of which are housed in the housing 16B.

The sheet 11B includes a circuit pattern 115, a first portion 113, and a second portion 114. Both of the circuit pattern 115 and the first portion 113 contain copper or a copper alloy. The second portion 114 has insulating properties, and is sandwiched between the circuit pattern 115 and the first portion 113. The sheet 11B is bonded to the housing 16B while at least a part of the first portion 113 (a surface of the first portion 113 opposite to the second portion 114) is exposed.

The semiconductor element 14 includes the first surface 14a, the second surface 14b, the first electrode 144, and the second electrode 145 (illustration omitted in FIG. 29; see FIG. 2), similarly to that in the semiconductor device 1A. The first surface 14a is bonded to the circuit pattern 115 through the first solder layer 131.

The block 17 is bonded to the second electrode 145 through the second solder layer 132, similarly to that in the semiconductor device 1A.

The first lead frame 104 is welded and bonded to the circuit pattern 115 through the welded portion 183. The second lead frame 105 is welded and bonded to the block 17 through the welded portions 181 and 182.

A sealant 16A has insulating properties, and has a linear coefficient of expansion more than or equal to 11 ppm/K and less than or equal to 21 ppm/K. The sealant 16A seals the first lead frame 104, the second lead frame 105, the sheet 11B, the lead frame group 10, the circuit pattern 115, the first solder layer 131, the second solder layer 132, the semiconductor element 14, and the block 17. The sealant 16A exposes the aforementioned part of the first portion 113, partly exposes the first lead frame 104 opposite to the circuit pattern 115, partly exposes the second lead frame 105 opposite to the block 17, and partly exposes the lead frame group 10 opposite to the electrode group 140.

The semiconductor device 1G further includes the wire group 12 (the wire 122 in FIG. 29; see FIG. 2) and the electrode group 140 (illustration omitted in FIG. 29; see FIG. 2), similarly to the semiconductor device 1A. The sealant 16A also seals the wire group 12 and the electrode group 140.

The sealant 16A in the semiconductor device 1G is formed by potting an insulator, for example, a resin into the space surrounded by the housing 16B. The sealant 16A is made of a material identical to that of the sealant 16 according to Embodiment 1.

Since the sealant 16A in the semiconductor device 1G has the linear coefficient of expansion more than or equal to 11 ppm/K and less than or equal to 21 ppm/K, the semiconductor device 1G less expensive and high in reliability can be obtained, similarly to that in Embodiment 1. The housing 16B with the linear coefficient of expansion more than or equal to 11 ppm/K and less than or equal to 21 ppm/K contributes to enhancement of the reliability. The housing 16B is made of, for example, a material identical to that of the sealant 16 according to Embodiment 1.

For example, the laser irradiation is adopted to welding the first lead frame 104 to the circuit pattern 115 and welding the second lead frame 105 to the block 17.

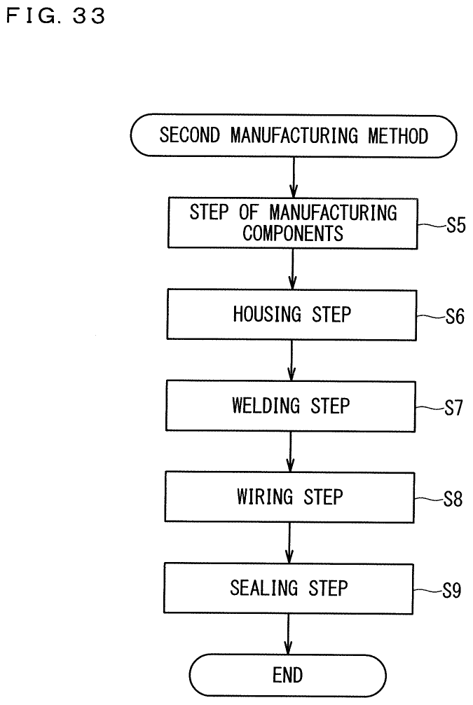

FIGS. 30 to 32 are cross-sectional views illustrating steps of manufacturing the semiconductor device 1G. The location of the cross-section of FIG. 1 is used in FIGS. 30 to 32. FIG. 33 is a flowchart exemplifying the manufacturing steps as a second manufacturing method.

FIG. 30 is a cross-sectional view illustrating a positional relationship between the first lead frame 104, the second lead frame 105, and the housing 16B. A part of the first lead frame 104 surrounded by the housing 16B is bonded to the circuit pattern 115 (for example, by laser irradiation). A part of the second lead frame 105 surrounded by the housing 16B is bonded to the block 17 (for example, by laser irradiation).

The housing 16B that buries the center of the first lead frame 104 and the center of the second lead frame 105 is manufactured by a known molding technology. Hereinafter, the housing 16B with the first lead frame 104 and the second lead frame 105 as described above will be provisionally referred to as a first component 301, and a step of manufacturing the first component 301 will be provisionally referred to as a first component manufacturing step for convenience. In the first component 301, the center of the lead frame group 10 (only the third lead frame 102 in FIG. 30) is also buried in the housing 16B.

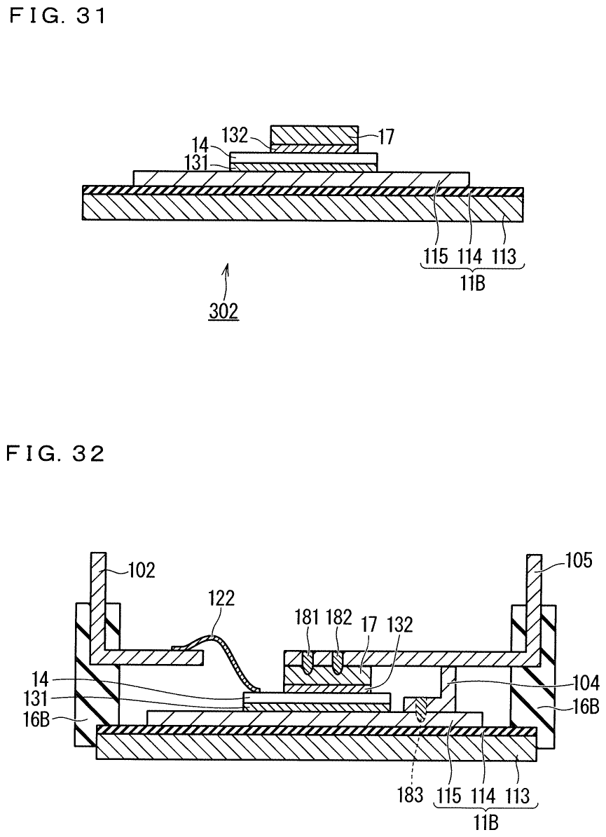

FIG. 31 is a cross-sectional view illustrating a positional relationship between the sheet 11B, the first solder layer 131, the second solder layer 132, the semiconductor element 14, and the block 17. The circuit pattern 115 is bonded to the semiconductor element 14 through the first solder layer 131. The semiconductor element 14 is bonded to the block 17 through the second solder layer 132. The aforementioned bonding produces a laminated structure of the sheet 11B, the first solder layer 131, the semiconductor element 14, the second solder layer 132, and the block 17. Hereinafter, this laminated structure will be provisionally referred to as a second component 302, and a step of manufacturing the second component 302 will be provisionally referred to as a second component manufacturing step for convenience.

The first component manufacturing step and the second component manufacturing step are independently executed. The order of executing the first component manufacturing step and executing the second component manufacturing step may be any.

The second manufacturing method includes Steps S5, S6, S7, S8, and S9. In Step S5, a step of manufacturing components is executed. The first component manufacturing step and the second component manufacturing step are executed in the step of manufacturing components.

After Step S5, Step S6 is executed. In Step S6, a housing step is executed. In the housing step, the second component 302 is housed in the first component 301, specifically, the housing 16B. Here, the sheet 11B is bonded to the housing 16B while at least a part of the first portion 113 is exposed.

After Step S6, Step S7 is executed. In Step S7, a welding step is executed. In the welding step, the first lead frame 104 is welded to the circuit pattern 115, and the second lead frame 105 is welded to the block 17.

After Step S7, Step S8 is executed. In Step S8, a wiring step is executed. In the wiring step, the lead frame group 10 and the electrode group 140 (illustration omitted; see FIG. 2) are connected through the wire group 12 (only the wire 122 in FIG. 32).

FIG. 32 is a cross-sectional view illustrating an end state of the wiring step. In this state, the circuit pattern 115, the semiconductor element 14, the block 17, the first solder layer 131, the second solder layer 132, and the wire group 12 are exposed. In this state, portions of the lead frame group 10 that are connected to the wire group 12, a portion of the first lead frame 104 that is bonded to the circuit pattern 115, and a portion of the second lead frame 105 that is bonded to the block 17 are also exposed.

After Step S8, Step S9 is executed. In Step S9, a sealing step is executed. The sealing step is sealing the sheet 11B with at least a part of the first portion 113 being exposed, sealing the first lead frame 104 with the first lead frame 104 being partly exposed opposite to the circuit pattern 115, sealing the second lead frame 105 with the second lead frame 105 being partly exposed opposite to the block 17, and sealing the circuit pattern 115, the first solder layer 131, the second solder layer 132, the semiconductor element 14, and the block 17. The sealing step applies, for example, potting a resin.

The end of the sealing step ends the second manufacturing method to produce the semiconductor device 1G (see FIG. 29).

The second manufacturing method contributes to manufacturing the semiconductor device 1G.

### Modification 1

Adopting, to the semiconductor devices 1A to 1F, a structure in which a hole is opened in the first lead frame 104 and a protrusion engaged into this hole protrudes opposite to the sheet 11A from the heat spreader 15 leads to the contribution similarly to Embodiment 2. Adopting, to the semiconductor device 1G, a structure in which a hole is opened in the first lead frame 104 and a protrusion engaged into this hole protrudes opposite to the sheet 11B from the circuit pattern 115 leads to the contribution similarly to Embodiment 2.

These structures contribute not only to facilitating positioning of the first lead frame 104 and the heat spreader 15 (or the circuit pattern 115) when they are welded and positioning of the second lead frame 105 and the block 17 when they are welded, but also to facilitating execution of the second step. These structures also contribute not only to facilitating positioning of the lead frame group 10 and the electrode group 140 when they are connected through the wire group 12, but also to facilitating execution of the third step.

### Modification 2

Without the protrusions 173, the protrusions 151 or the bumps 125 in Embodiment 4 prevent the first solder layer 131 being melted from extending beyond the first surface 14a when the semiconductor element 14 is curved by the weight of the block 17 in the first step.

Without the protrusions 151 and the bumps 125, the protrusions 173 in Embodiment 4 prevent the second solder layer 132 being melted from extending beyond the second surface 14b due to the curved semiconductor element 14.

Embodiments can be freely combined, and appropriately modified or omitted. For example, the protrusion 171 described in Embodiment 2 is applicable to any one of the semiconductor devices 1A, 1C, 1Da, 1Db, 1E, 1F, and 1G. For example, the surface 172 described in Embodiment 3 is applicable to any one of the semiconductor devices 1A, 1B, 1Da, 1Db, 1E, 1F, and 1G. For example, any one or more of the protrusions 151, the protrusions 173, and the bumps 125 described in Embodiment 4 are applicable to any one of the semiconductor devices 1A, 1B, 1C, 1E, 1F, and 1G.

The following will describe a summary of various aspects of the present disclosure as appendixes.

[Appendix 1] A semiconductor device, comprising:
a heat spreader made of copper or a copper alloy;
a first solder layer;
a second solder layer;
a semiconductor element including a first surface bonded to the heat spreader through the first solder layer, a second surface facing the first surface, a first electrode disposed on the first surface, and a second electrode disposed on the second surface;
a block bonded to the second electrode through the second solder layer, the block being made of copper or a copper alloy;
a sheet including a first portion made of copper or a copper alloy, and a second portion having insulating properties and being in contact with the heat spreader;
a first lead frame welded to the heat spreader and made of copper or a copper alloy;
a second lead frame welded to the block and made of copper or a copper alloy; and
a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the heat spreader, sealing the second lead frame with the second lead frame being partly exposed opposite to the block, and sealing the heat spreader, the first solder layer, the second solder layer, the semiconductor element, and the block.
   [Appendix 2] A semiconductor device, comprising:
a heat spreader made of copper or a copper alloy;
a first solder layer;
a second solder layer;
a third solder layer having a melting point lower than a first melting point that is a lower one of a melting point of the first solder layer and a melting point of the second solder layer;
a fourth solder layer having a melting point lower than the first melting point;
a semiconductor element including a first surface bonded to the heat spreader through the first solder layer, a second surface facing the first surface, a first electrode disposed on the first surface, and a second electrode disposed on the second surface;
a block bonded to the second electrode through the second solder layer, the block being made of copper or a copper alloy;
a sheet including a first portion made of copper or a copper alloy, and a second portion having insulating properties and being in contact with the heat spreader;
a first lead frame bonded to the heat spreader through the third solder layer and made of copper or a copper alloy;
a second lead frame bonded to the block through the fourth solder layer and made of copper or a copper alloy; and
a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the heat spreader, sealing the second lead frame with the second lead frame being partly exposed opposite to the block, and sealing the heat spreader, the first solder layer, the second solder layer, the semiconductor element, and the block.
   [Appendix 3] The semiconductor device according to appendix 2,
wherein a first hole is opened, inside which the third solder layer is, in the first lead frame, and a second hole is opened, inside which the fourth solder layer is, in the second lead frame.
   [Appendix 4] The semiconductor device according to any one of appendixes 1 to 3,
wherein the second lead frame includes a hole adjacent to portions bonded to the block, and
the block incudes a protrusion protruding opposite to the semiconductor element and being inside the hole.
   [Appendix 5] The semiconductor device according to any one of appendixes 1 to 4, further comprising:
a third lead frame; and
a wire connected to the third lead frame,
wherein the semiconductor element further includes a third electrode disposed on the second surface and connected to the third lead frame through the wire, and
the block includes a surface closer to the third lead frame, the surface having an increasing distance from the third lead frame with distance away from the second surface.
   [Appendix 6] The semiconductor device according to any one of appendixes 1 to 5,
wherein the block includes three or more protrusions protruding toward the semiconductor element.
   [Appendix 7] The semiconductor device according to any one of appendixes 1 to 6,
wherein the heat spreader includes three or more protrusions protruding toward the semiconductor element.
   [Appendix 8] The semiconductor device according to any one of appendixes 1 to 7, further comprising
a bump between the first surface and the heat spreader, the bump being made of a metal.
   [Appendix 9] A method of manufacturing the semiconductor device according to appendix 2 or 3, the method comprising:
bonding the semiconductor element to the heat spreader through the first solder layer, and the semiconductor element to the block through the second solder layer;
melting a first solder alloy at a temperature lower than the first melting point to form the third solder layer, and a second solder alloy at a temperature lower than the first melting point to form the fourth solder layer, the melting being executed after the bonding; and
forming the sealant, the forming being executed after the melting.
   [Appendix 10] The method according to appendix 9,
wherein the melting includes performing laser irradiation to melt the first solder alloy and the second solder alloy.
   [Appendix 11] A semiconductor device, comprising:
a first lead frame;
a second lead frame;
a housing being tubular and having insulating properties and burying a center of the first lead frame and a center of the second lead frame;
a sheet including a circuit pattern made of copper or a copper alloy and bonded to the first lead frame, a first portion made of copper or a copper alloy, and a second portion having insulating properties and sandwiched between the circuit pattern and the first portion, the sheet being housed in the housing with at least a part of the first portion being exposed;
a first solder layer housed in the housing;
a second solder layer housed in the housing;
a semiconductor element including a first surface, a second surface facing the first surface, a first electrode disposed on the first surface and bonded to the circuit pattern through the first solder layer, and a second electrode disposed on the second surface, the semiconductor element being housed in the housing;
a block bonded to the second electrode through the second solder layer and bonded to the second lead frame, the block being made of copper or a copper alloy and being housed in the housing; and
a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the circuit pattern, sealing the second lead frame with the second lead frame being partly exposed opposite to the block, and sealing the circuit pattern, the first solder layer, the second solder layer, the semiconductor element, and the block.
   [Appendix 12] A method of manufacturing a semiconductor device, the method comprising:
manufacturing a first component and a second component,
   the first component including:
      a housing being tubular and having insulating properties;
      a first lead frame including a center buried in the housing; and
      a second lead frame including a center buried in the housing; and
   the second component including:
      a sheet including a circuit pattern made of copper or a copper alloy, a first portion made of copper or a copper alloy, and a second portion having insulating properties and sandwiched between the circuit pattern and the first portion;
      a first solder layer;
      a second solder layer;
      a semiconductor element including a first surface bonded to the circuit pattern through the first solder layer, a second surface facing the first surface, a first electrode disposed on the first surface, and a second electrode disposed on the second surface; and
   a block bonded to the second electrode through the second solder layer, the block being made of copper or a copper alloy;
bonding the sheet to the housing with at least a part of the first portion being exposed, and housing the second component in the first component;
welding the first lead frame to the circuit pattern and welding the second lead frame to the block, the welding being executed after the bonding and the housing; and
sealing, using a sealant having insulating properties and having a linear coefficient of expansion more than or equal to 11 ppm/K and less than or equal to 21 ppm/K, the sheet with at least the part of the first portion being exposed, the first lead frame with the first lead frame being partly exposed opposite to the circuit pattern, the second lead frame with the second lead frame being partly exposed opposite to the block, and the circuit pattern, the first solder layer, the second solder layer, the semiconductor element, and the block, the scaling being executed after the welding.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a heat spreader made of copper or a copper alloy;
a first solder layer;
a second solder layer;
a semiconductor element including a first surface bonded to the heat spreader through the first solder layer, a second surface facing the first surface, a first electrode disposed on the first surface, and a second electrode disposed on the second surface;
a block bonded to the second electrode through the second solder layer, the block being made of copper or a copper alloy;
a sheet including a first portion made of copper or a copper alloy, and a second portion having insulating properties and being in contact with the heat spreader;
a first lead frame welded to the heat spreader and made of copper or a copper alloy;
a second lead frame welded to the block and made of copper or a copper alloy; and
a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the heat spreader, sealing the second lead frame with the second lead frame being partly exposed opposite to the block, and sealing the heat spreader, the first solder layer, the second solder layer, the semiconductor element, and the block.

2. A semiconductor device, comprising:
a heat spreader made of copper or a copper alloy;
a first solder layer;
a second solder layer;
a third solder layer having a melting point lower than a first melting point that is a lower one of a melting point of the first solder layer and a melting point of the second solder layer;
a fourth solder layer having a melting point lower than the first melting point;
a semiconductor element including a first surface bonded to the heat spreader through the first solder layer, a second surface facing the first surface, a first electrode disposed on the first surface, and a second electrode disposed on the second surface;
a block bonded to the second electrode through the second solder layer, the block being made of copper or a copper alloy;
a sheet including a first portion made of copper or a copper alloy, and a second portion having insulating properties and being in contact with the heat spreader;
a first lead frame bonded to the heat spreader through the third solder layer and made of copper or a copper alloy;
a second lead frame bonded to the block through the fourth solder layer and made of copper or a copper alloy; and
a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the heat spreader, sealing the second lead frame with the second lead frame being partly exposed opposite to the block, and sealing the heat spreader, the first solder layer, the second solder layer, the semiconductor element, and the block.

3. The semiconductor device according to claim 2,
wherein a first hole is opened, inside which the third solder layer is, in the first lead frame, and a second hole is opened, inside which the fourth solder layer is, in the second lead frame.

4. The semiconductor device according to claim 1,
wherein a hole is opened in the second lead frame adjacent to portions bonded to the block, and
the block includes a protrusion protruding opposite to the semiconductor element and being inside the hole.

5. The semiconductor device according to claim 2,
wherein a hole is opened in the second lead frame adjacent to portions bonded to the block, and
the block incudes a protrusion protruding opposite to the semiconductor element and being inside the hole.

6. The semiconductor device according to claim 1, further comprising:
a third lead frame; and
a wire connected to the third lead frame,
wherein the semiconductor element further includes a third electrode disposed on the second surface and connected to the third lead frame through the wire, and
the block includes a surface closer to the third lead frame, the surface having an increasing distance from the third lead frame with distance away from the second surface.

7. The semiconductor device according to claim 2, further comprising:
a third lead frame; and
a wire connected to the third lead frame,
wherein the semiconductor element further includes a third electrode disposed on the second surface and connected to the third lead frame through the wire, and
the block includes a surface closer to the third lead frame, the surface having an increasing distance from the third lead frame with distance away from the second surface.

8. The semiconductor device according to claim 1,
wherein the block includes three or more protrusions protruding toward the semiconductor element.

9. The semiconductor device according to claim 2,
wherein the block includes three or more protrusions protruding toward the semiconductor element.

10. The semiconductor device according to claim 1,
wherein the heat spreader includes three or more protrusions protruding toward the semiconductor element.

11. The semiconductor device according to claim 2,
wherein the heat spreader includes three or more protrusions protruding toward the semiconductor element.

12. The semiconductor device according to claim 1, further comprising
a bump between the first surface and the heat spreader, the bump being made of a metal.

13. The semiconductor device according to claim 2, further comprising
a bump between the first surface and the heat spreader, the bump being made of a metal.

14. A method of manufacturing the semiconductor device according to claim 2, the method comprising:
bonding the semiconductor element to the heat spreader through the first solder layer, and the semiconductor element to the block through the second solder layer;
melting a first solder alloy at a temperature lower than the first melting point to form the third solder layer, and a second solder alloy at a temperature lower than the first melting point to form the fourth solder layer, the melting being executed after the bonding; and
forming the sealant, the forming being executed after the melting.

15. The method according to claim 14,
wherein a first hole is opened, inside which the third solder layer is, in the first lead frame, and a second hole is opened, inside which the fourth solder layer is, in the second lead frame.

16. The method according to claim 14,
wherein the melting includes performing laser irradiation to melt the first solder alloy and the second solder alloy.

17. The method according to claim 15,
wherein the melting includes performing laser irradiation to melt the first solder alloy and the second solder alloy.

18. A semiconductor device, comprising:
a first lead frame;
a second lead frame;
a housing being tubular and having insulating properties and burying a center of the first lead frame and a center of the second lead frame;
a sheet including a circuit pattern made of copper or a copper alloy and bonded to the first lead frame, a first portion made of copper or a copper alloy, and a second portion having insulating properties and sandwiched between the circuit pattern and the first portion, the sheet being housed in the housing with at least a part of the first portion being exposed;
a first solder layer housed in the housing;
a second solder layer housed in the housing;
a semiconductor element including a first surface, a second surface facing the first surface, a first electrode disposed on the first surface and bonded to the circuit pattern through the first solder layer, and a second electrode disposed on the second surface, the semiconductor element being housed in the housing;
a block bonded to the second electrode through the second solder layer and bonded to the second lead frame, the block being made of copper or a copper alloy and being housed in the housing; and
a sealant having insulating properties and having a linear coefficient of expansion more than or equal to 11 ppm/K and less than or equal to 21 ppm/K, the sealant sealing the sheet with at least a part of the first portion being exposed, sealing the first lead frame with the first lead frame being partly exposed opposite to the circuit pattern, sealing the second lead frame with the second lead frame being partly exposed opposite to the block, and sealing the circuit pattern, the first solder layer, the second solder layer, the semiconductor element, and the block.

19. A method of manufacturing a semiconductor device, the method comprising:
manufacturing a first component and a second component,
the first component including:
a housing being tubular and having insulating properties;
a first lead frame including a center buried in the housing; and
a second lead frame including a center buried in the housing; and
the second component including:
a sheet including a circuit pattern made of copper or a copper alloy, a first portion made of copper or a copper alloy, and a second portion having insulating properties and sandwiched between the circuit pattern and the first portion;
a first solder layer;
a second solder layer;
a semiconductor element including a first surface bonded to the circuit pattern through the first solder layer, a second surface facing the first surface, a first electrode disposed on the first surface, and a second electrode disposed on the second surface; and
a block bonded to the second electrode through the second solder layer, the block being made of copper or a copper alloy;
bonding the sheet to the housing with at least a part of the first portion being exposed, and housing the second component in the first component;
welding the first lead frame to the circuit pattern and welding the second lead frame to the block, the welding being executed after the bonding and the housing; and
sealing, using a sealant having insulating properties and having a linear coefficient of expansion more than or equal to 11 ppm/K and less than or equal to 21 ppm/K, the sheet with at least the part of the first portion being exposed, the first lead frame with the first lead frame being partly exposed opposite to the circuit pattern, the second lead frame with the second lead frame being partly exposed opposite to the block, and the circuit pattern, the first solder layer, the second solder layer, the semiconductor element, and the block, the sealing being executed after the welding.
